(19) United States
(12) Patent Application Publication
(10) Pub. No.: US 2018/0219065 A1
(43) Pub. Date: Aug. 2, 2018

(54) Insulation Structure Including a Gas Filled Cavity

(71) Applicant: Infineon Technologies Austria AG, Villach (AT)

(72) Inventor: Hans Weber, Bayerisch Gmain (DE)

(21) Appl. No.: 15/881,128

(22) Filed: Jan. 26, 2018

(30) Foreign Application Priority Data
Jan. 27, 2017 (DE) 102017101672.4

(51) Int. Cl. H01L 29/06; H01L 21/308; H01L 21/02; H01L 29/04; H01L 21/306; H01L 21/265; H01L 21/266; H01L 21/78; H01L 21/8234; H01L 21/764

(52) U.S. Cl. CPC H01L 29/0661; H01L 21/308; H01L 21/02236; H01L 29/045; H01L 21/30604; H01L 21/26586; H01L 29/861; H01L 21/78; H01L 21/823481; H01L 29/0649; H01L 21/26513; H01L 21/764; H01L 21/266

(57) ABSTRACT

A method and a semiconductor device are disclosed. The method includes forming an etch mask on top of a surface of an edge region of a semiconductor body, the edge region surrounding an inner region of the semiconductor body, the etch mask having a plurality of openings and at least one bridge between the openings. The method further includes etching the semiconductor body at least in regions uncovered by the plurality of openings to form at least one cavity in the semiconductor body, closing the plurality of openings such that the at least one cavity remains in the semiconductor body, and forming active device regions of a semiconductor device in the inner region.

### BACKGROUND

A trench insulation structure includes a trench filled with a dielectric in a semiconductor body. Such trench insulation structure may be used, for example, in an edge termination structure of a vertical power semiconductor device such as a power MOSFET (Metal Oxide Semiconductor Field-Effect Transistors), a power IGBT (Insulated Gate Bipolar Transistors), or a power diode.

There is a need to provide a method that produces a space efficient trench insulation structure, is compatible with manufacturing processes of power semiconductor devices, and cost efficient.

### SUMMARY

One example relates to a method that includes forming an etch mask on top of a surface of a semiconductor body, wherein the etch mask comprises a plurality of openings and at least one bridge between the openings, etching the semiconductor body at least in regions uncovered by the plurality of openings to form at least one cavity in the semiconductor body, and closing the plurality of openings such that the at least one cavity remains in the semiconductor body.

A method according to another example includes, in a first irradiation process, irradiating a surface of a first implantation mask formed on an opening of a first cavity in a semiconductor body and a surface of a second implantation mask formed on an opening of a second cavity in the semiconductor body with dopant particles. The first irradiation process uses a first implantation vector, and the first implantation mask includes a plurality of openings that are oriented relative to the first implantation vector such that dopant atoms pass the first implantation mask and are implanted into a first sidewall of the first cavity. The second implantation mask includes a plurality of openings separated by bridges, and the openings and bridges in the second implantation mask are oriented such that dopant atoms do not pass the second implantation mask.

Another example relates to a semiconductor device with a trench insulation structure. The trench insulation structure includes a cavity filled with a gas in a semiconductor body and a cover on top of the cavity. The cover includes a web with a plurality of openings and a material layer that at least one of fills and covers the plurality of openings.

Those skilled in the art will recognize additional features and advantages upon reading the following detailed description, and upon viewing the accompanying drawings.

### BRIEF DESCRIPTION OF THE FIGURES

Examples are explained below with reference to the drawings. The drawings serve to illustrate certain principles, so that only aspects necessary for understanding these principles are illustrated. The drawings are not to scale. In the drawings the same reference characters denote like features.

FIGS. 1A-1E illustrate one example of a method for forming a trench insulation structure that includes at least one cavity in a semiconductor body.

FIGS. 2A-2B illustrate one example of a method for patterning an etch mask of the type shown in FIGS. 1A-1E.

FIGS. 3-5 show different examples of patterned etch masks.

FIGS. 6A-6D illustrate one example of a method for forming one cavity in a semiconductor body.

FIGS. 7A-7D illustrate one example of a method for forming a plurality of cavities in a semiconductor body.

FIGS. 8A-8F illustrate another example of a method for forming a plurality of cavities.

FIGS. 9A-9D illustrate another example of a method for forming one cavity in a semiconductor body.

FIGS. 10A-10B illustrate one example of a method for forming an insulation layer on the bottom and sidewalls of a cavity in a semiconductor body.

FIG. 11 shows a top view of a semiconductor body 2 with an inner region and an edge region and with a trench insulation structure formed in the edge region an surrounding the inner region.

FIG. 12 shows a top view of a semiconductor body including an inner region and an edge region and a trench insulation structure with two spaced apart sections in the edge region.

FIG. 13 shows a vertical cross sectional view of a section of the inner region and the trench insulation structure shown in one of FIGS. 11 and 12.

FIG. 14 shows a vertical cross sectional view of a section of an inner region and an edge region including an optional planar edge termination structure of the semiconductor body shown in FIG. 12.

FIG. 15 shows a vertical cross sectional view of one section of a semiconductor device implemented as a diode.

FIG. 16 shows a vertical cross sectional view of one section of a semiconductor device implemented as a transistor.

FIGS. 17A-17F illustrate one example of a method for forming a doped region in a semiconductor body along a trench isolation structure of the type shown in FIG. 12.

FIG. 18 shows a vertical cross sectional view of a semiconductor body that includes at least two trench insulation structures.

FIG. 19 shows another example of a semiconductor body that includes at least two trench insulation structures.

FIG. 20 schematically illustrates a top view of a trench insulation structure according to another example.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

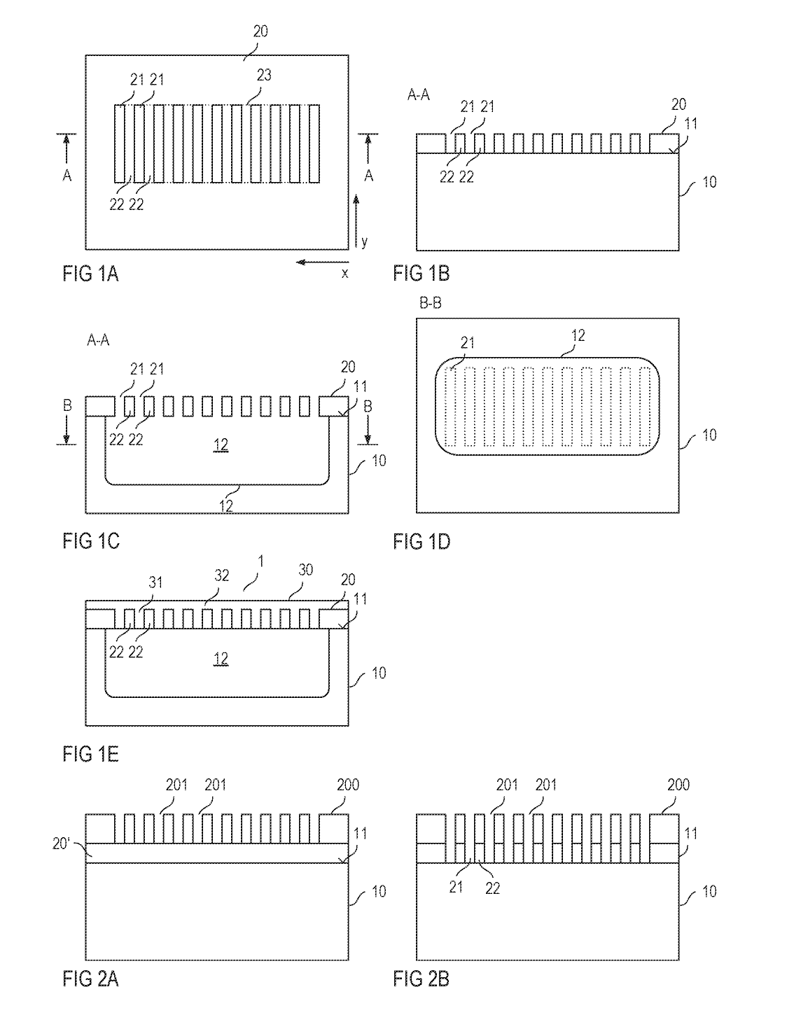

FIGS. 1A-1E illustrate one example of a method for forming a trench insulation structure in a semiconductor body 10. The method uses a patterned etch mask 20 formed on top of a first surface 11 of the semiconductor body 10. FIGS. 1A-1E show the arrangement with the semiconductor body 10 and the patterned etch mask 20 in or after different method steps (process steps). It should be noted that these FIGS. 1A-1E only show one section of the semiconductor body 10, namely the section in which the trench insulation structure is formed. The semiconductor body 10 may include any type of (monocrystalline) semiconductor material that can be used to form semiconductor devices. Examples of those semiconductor materials include, but are not restricted to, silicon (Si), silicon carbide (SiC), gallium nitride (GaN), gallium arsenide (GaAs), or the like.

FIG. 1A shows a top view of the etch mask 20 formed on top of the first surface 11 of the semiconductor body, and FIG. 1B shows a vertical cross sectional view of the arrangement with the semiconductor body 10 and the etch mask 20 in a vertical section plane A-A. The position of the vertical section plane A-A in the horizontal plane of the arrangement is illustrated in FIG. 1A. The vertical section plane A-A cuts through the semiconductor body 10 and the etch mask 20 and is essentially perpendicular to the first surface 11. The etch mask 20 includes a plurality of openings 21 and at least one bridge 22 between the openings 21. A section 21 of the etch mask 20 that includes the plurality of openings 21 and the at least one bridge 22 is referred to as patterned section 23 of the etch mask 20 in the following. An outer contour of this patterned section is illustrated by dotted lines in FIG. 1A (and the other figures).

Referring to FIG. 1B, the openings 21 go through the etch mask 20 so that sections of the first surface 11 of the semiconductor body 10 are uncovered at bottoms of the individual openings 21. Just for the purpose of illustration, in FIG. 1A, the openings 21 are drawn as elongated openings which are essentially parallel. However, referring to the explanation herein further below, openings with other contours may be used as well.

Referring to FIGS. 1C and 1D, the method further includes etching the semiconductor body 10 with the etch mask in place to form at least one cavity 12 in the semiconductor body 10 below the etch mask 20. FIG. 1C shows a vertical cross sectional view of the arrangement with the semiconductor body 10 and the etch mask 20 after the etching process and FIG. 1D shows a horizontal cross sectional view in a section plane B-B shown in FIG. 1C after the etching process. The horizontal section plane B-B cuts through the semiconductor body 10 and the at least one cavity 12 and is essentially parallel to the first surface 11. In the example shown in FIGS. 1C and 1D, the semiconductor body 10, after the etching process, includes one cavity. This, however, is only an example. According to another example, more than one cavity is formed in the semiconductor body 10 below the etch mask. Examples of methods for forming one or more than one cavity in the semiconductor body 10 below the etch mask 20, in particular below the patterned section 23 of the etch mask 20, are explained in further detail herein below.

Referring to FIG. 1E, the method further includes closing the plurality of openings 21 such that the at least one cavity 12 remains in the semiconductor body 10. This is illustrated in FIG. 1E, which shows a vertical cross sectional view of the arrangement with the semiconductor body 10 and the etch mask 20 after closing the plurality of openings 21. “Closing the plurality of openings” includes filling the openings 21 with a filling material and/or covering the openings 21 and the least one bridge 22 with a covering layer. According to one example shown in FIG. 1E, a material layer 30 may be formed that fills the openings 21 and covers the openings 21 and the at least one bridge 22. This material layer 30 is also referred to as sealing layer in the following. The etch mask 20 and the sealing layer 30 form a cover that covers and seals the at least one cavity 12 remaining in the semiconductor body 10. The trench insulation structure, which, as a whole, is labelled with reference character 1 in the following, therefore includes at least one cavity 12 covered by the etch mask 20 that was used in the manufacturing process of the at least one cavity 12 and a sealing layer, such as sealing 30 shown in FIG. 1E.

According to one example, the sealing layer 30 is formed in a deposition process such as a chemical vapor deposition (CVD) process. In this process, the sealing layer 30 “grows” on the at least bridge 22 on sidewalls of the openings 21 and, optionally, on top of the at least one bridge 22. In this example, a duration of the deposition process is chosen long enough for the growing sealing layer 30 to completely close the plurality of openings 21.

In the method explained above, at least the patterned section 23 of the etch mask 20 stays in place after the etching process and becomes a part of the cover. The at least one bridge 22 forms a web (skeletal structure) of the cover, so that only the relatively small openings 21 (instead of one big opening formed by the cavity 12) need to be closed in order to cover and seal the cavity 12. “Relatively small” means that the openings 21 are significantly smaller in size than the size of the cavity 12 in horizontal directions. “Horizontal directions” are directions parallel to the first surface 11. According to one example the openings 21 are such that there is no position in the openings 21 that is more distant to the bridge 22 than between 50 nanometers (nm) and 5 micrometers (μm), in particular between 300 nanometers and 1 micrometer. A thickness of the etch mask 20 is, for example, between 100 nanometers and 3 micrometers, in particular between 500 nanometers and 2 micrometers.

According to one example, both the etch mask 20 and the sealing layer 30 are electrically insulating. According to one example, a material of the etch mask 20 and a material of the sealing layer 30 are adapted to one another such that the material of the sealing layer 30 adheres at the at least one bridge 22 of the etch mask 20 in the manufacturing process of the sealing layer 30. According to one example, the etch mask 20 includes at least one of an oxide, such as silicon oxide (SiO₂), and a nitride, such as silicon nitride (SiN). The etch mask 20 may include only one layer of one material or may include a layer stack with at least two layers of different materials. According to one example, the sealing layer 30 includes at least one of an oxide, a nitride, an imide, or carbon, such as DLC (Diamond Like Carbon). The sealing layer 30 may include only one layer of one material or may include a layer stack with at least two layers of different materials.

In the process of forming the sealing layer 30 a layer of the same material as the sealing layer 30 may be deposited on the sidewalls and a bottom of the cavity 12 before the cavity is closed. However, such layer on the sidewalls and the bottom of the cavity 12 is not shown in FIG. 1E. According to one example, the semiconductor body 100 is heated in a hydrogen atmosphere after forming the cavity 12 and before or during forming the sealing layer. This helps to passivate the sidewalls and the bottom of the cavity and, for example, to saturate dangling bonds.

The cavity 12 in the trench insulation structure 1 shown in FIG. 1E is filled with a gas. The cavity 12 is already filled with a gas before the sealing layer is formed 30. The type of gas is dependent on an atmosphere in which the sealing layer 23 is formed. According to one example, the gas includes hydrogen (H₂). Further, gas atoms may diffuse from the semiconductor body 10 or from the atmosphere (for example, during an annealing process in a hydrogen atmosphere) into the cavity 12 after the cavity has been closed. The gas filling the cavity acts as a dielectric, whereas the relative dielectric constant (permittivity) of air and nitrogen, for example, is close to 1. Other than a cavity filled with a solid dielectric, such as an oxide, a cavity filled with a gas, does not cause mechanical stress in the semiconductor body. When using a solid dielectric such stress may result from different coefficients of thermal expansion in the semiconductor body and the solid dielectric.

Summarizing the above, using the method explained above a trench insulation structure 1 with a wide cavity 12 may be formed. The method not only provides for covering a wide cavity 12, but the wide cavity 12, by virtue of being filled with a gas, does not cause mechanical stress in the semiconductor body 12. A depth of the cavity 12, that is, a dimension of the cavity in a direction perpendicular to the first surface 11, is, for example, dependent on the specific type of semiconductor device. According to one example the semiconductor device is a vertical power semiconductor device with a drift region (or base region). Examples of a vertical power semiconductor device are explained with reference to FIGS. 15 and 16 below, in which reference character 51 denotes the drift region (base region). The drift region (base region) has a length in the vertical direction of the semiconductor body 100. According to one example, the depth of the cavity 12 is at least 70%, at least 80%, at least 90%, or at least 100% of the length of the drift region (base region). According to another example, the depth of the cavity 12 is at least 30 micrometers or at least 40 micrometers.

The plurality of openings 21 in the etch mask 20 may be formed in an etching process. This is illustrated in FIGS. 2A and 2B which each illustrate a vertical cross sectional view of the semiconductor body 10 and the etch mask 20 in the manufacturing process of the openings 21.

Referring to FIG. 2A, forming the patterned etch mask 20 may include forming an etch mask layer 20′ on top of the first surface 11 and forming another patterned etch mask 200 on top of the etch mask layer 20′. The other etch mask 200 includes a plurality of openings 201, wherein a size and positions of the openings 201 in the other etch mask 200 define the size and position of the openings 21 in the etch mask 20 explained with reference to FIGS. 1A-1E. According to one example, the other etch mask 200 includes a photoresist. Additionally or alternatively to the photoresist the other etch mask may include a hard mask such as a polysilicon hard mask. Referring to FIG. 2B, forming the etch mask 20 further includes etching the etch mask layer 20′ in an etching process such that openings 21 are formed in the etch mask 20 at positions defined by the openings 201 of the other etch mask 200. According to one example, the other etch mask 200 is removed after this etching process, so as to obtain a structure as shown in FIG. 1B.

In the example shown in FIG. 1A, the patterned section 23 of the etch mask 20 includes a plurality of elongated openings 21 and a plurality elongated bridges 22, with each bridge 22 being located between two neighbouring openings 21. Further, a shape of the patterned section 23 is of essentially rectangular form in the example shown in FIG. 1A, and the openings 21 extend from one side to an opposing side of the rectangular patterned section 23. This, however, is only an example. FIGS. 3 to 5 illustrate other examples of how the etch mask 20 may be patterned.

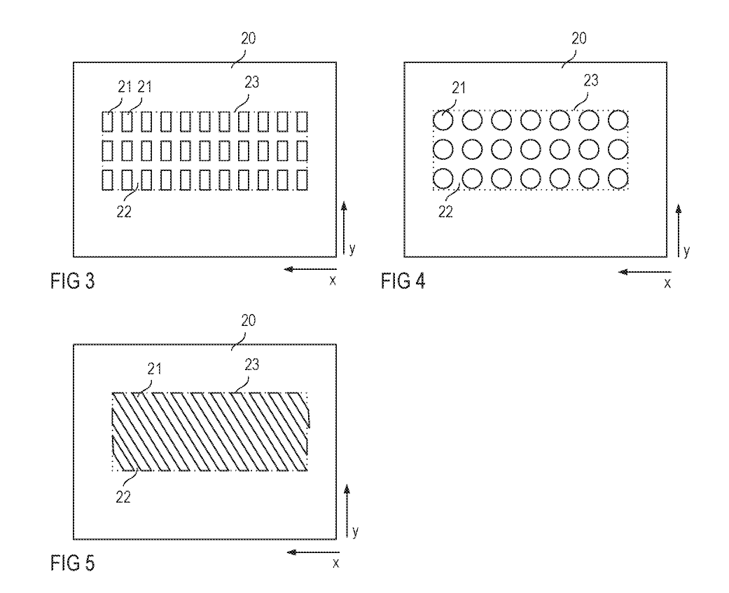

In the example shown in FIG. 3, the patterned section 23 includes a plurality of openings 21 that are spaced apart in a first horizontal direction x and a second horizontal direction y of the semiconductor body 10 and the etch mask 20. The openings 21 shown in FIG. 3 are essentially of rectangular form. This, however, is only an example. According to another example shown in FIG. 4 circular openings 21 may be used as well. According to another example (not shown) the openings 21 are of elliptical or polygonal form.

In the example shown in FIG. 1A, the rectangular shape of the patterned section 23 has two sides extending in the first horizontal direction x and two sides extending in the second horizontal direction y of the etch mask 20 and the semiconductor body 10 (which is out of view in FIG. 1A). The openings 21 are essentially perpendicular to the first horizontal direction x and essentially parallel to the second horizontal direction y. According to another example shown in FIG. 5, a plurality of elongated openings 21 of the etch mask are inclined relative to the first horizontal direction x. That is, an angle between the elongated openings 21 and the first horizontal direction x is different from 90°. According to one example, this angle is selected form between 20° and 70°, in particular between 30° and 60°.

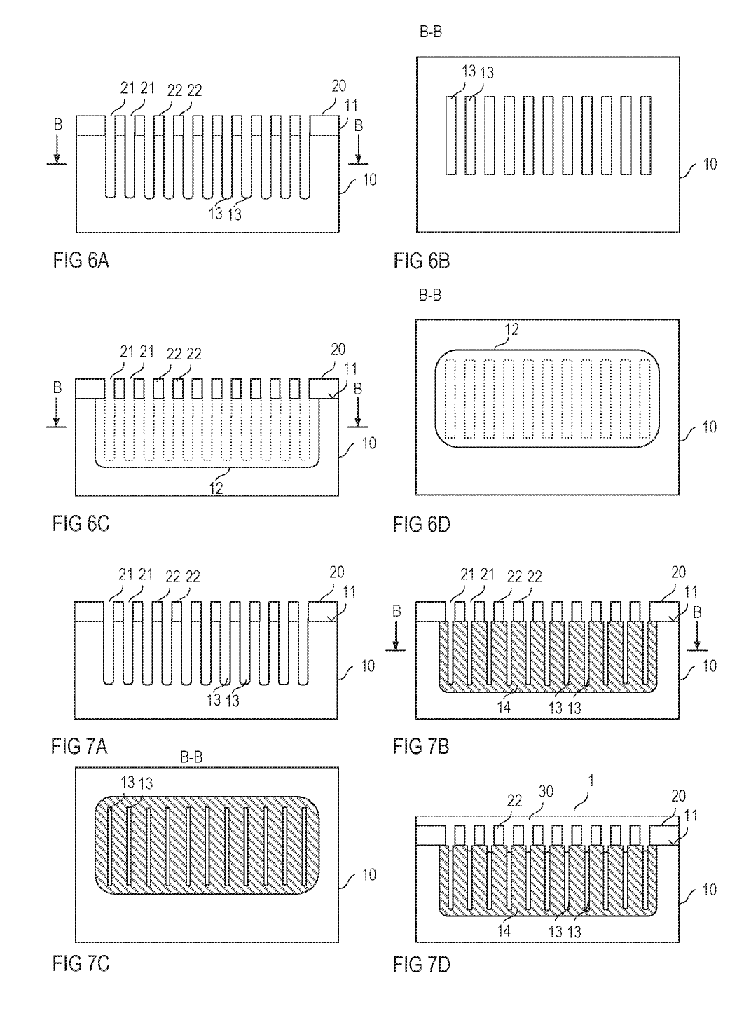

FIGS. 6A-6D illustrate one example of a method for forming a cavity 12 of the type shown in FIGS. 1C and 1D. Referring to FIGS. 6A and 6B, this method includes forming a plurality of trenches 13, each extending form the first surface 11 into the semiconductor body 100, in a first etching process. These trenches 13 are aligned with the openings 21 in the etch mask 20. That is, a position and a form of each of these trenches 13 in the horizontal plane corresponds to a position and size of a corresponding opening 21 in the etch mask 20. FIG. 6A shows a vertical cross sectional view of the semiconductor body 10 and the etch mask 20 after forming the plurality of trenches 13. FIG. 6B shows a horizontal cross sectional view of the semiconductor body 10 in a horizontal section plane B-B (that is essentially parallel to the first surface 11). Forming the plurality of trenches 13 may include an anisotropic etching process that essentially etches the semiconductor body 10 in a vertical direction in those regions uncovered by the openings 21 of the etch mask 20. The “vertical direction” is a direction perpendicular to the first surface 11.

Referring to FIGS. 6C and 6D, the method further includes a second etching process that removes material of the semiconductor body 10 below the at least one bridge 22, that is, between the plurality of trenches 13. FIG. 6C shows a vertical cross sectional view of the semiconductor body 10 and the etch mask 20 and FIG. 6D shows a horizontal cross sectional view in the section plane B-B after this further etching process. The form and the position of the plurality of trenches 13 before the further etching process are illustrated in dotted lines in FIGS. 6C and 6D. According to one example, the second etching process is an isotropic etching process that etches the semiconductor body 10 in vertical and horizontal directions. According to another example, the second etching process is another anisotropic etching process, one that etches the semiconductor body 10 in a lateral direction such that the semiconductor material between the plurality of trenches 13 is removed. The cavity 12 resulting from the second etching process may be deeper than the trenches 13 formed in the etching process explained with reference to FIGS. 6A and 6B. An “anisotropic etching process” is an etching process that etches the semiconductor body 10 in at least on direction much faster than in at least one other direction.

FIGS. 7A-7D illustrate another example of a method for forming at least one cavity in the semiconductor body 10. This method is based on the method explained with reference to FIGS. 6A and 6D and is different from the method explained with reference to FIGS. 6A and 6D in that there is an oxidation process instead of the second etching process. FIG. 7A shows a vertical cross sectional view of the arrangement after forming the plurality of trenches 13 in an etching process of the type explained with reference to FIGS. 6A and 6B. FIG. 7B shows a vertical cross sectional view and FIG. 7C shows a horizontal cross sectional view of the arrangement after the oxidation process. In this oxidation process, regions of the semiconductor body 10 uncovered at bottoms and sidewalls of the plurality of trenches 13 are oxidized. According to one example, a temperature and a duration of this oxidation process is such that semiconductor regions between the trenches 13 are completely oxidized so that the trenches 13 are finally separated by oxide regions instead of semiconductor regions. In FIGS. 7B and C, oxidized regions of the semiconductor body 10 after this oxidation process are labelled with reference character 14.

FIG. 7D shows a trench insulation structure 1 that is based on the arrangement shown in FIGS. 7B and 7C. This trench insulation structure is obtained by closing the openings 21 in the etch mask 20 in the way explained with reference to FIG. 1E before. The trench insulation structure shown in FIG. 7D is different from the trench insulation structure shown in FIG. 1E in that it includes a plurality of cavities (trenches) 13 that are covered (sealed) by a cover including the etch mask 20 and the sealing layer 30.

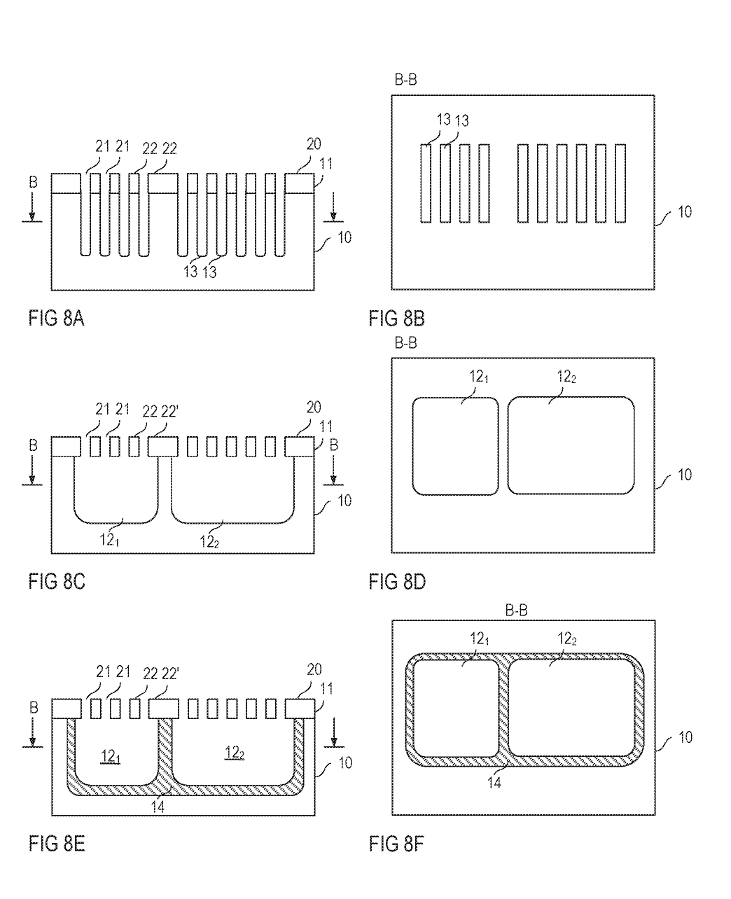

FIGS. 6A-6D illustrate a method for forming only one cavity 12 based on a plurality of openings 21 in the etch mask 20, and FIGS. 7A-7D illustrate a method for forming a plurality of cavities 13, whereas the number of cavities 13 is equal the number of openings 21 in the etch mask 20. FIGS. 8A-8F show one example of a method for producing more than one cavity but less cavities than openings 21 in the etch mask 20. This method is a combination of the methods explained with reference to FIGS. 6A-6D and 7A-7D before.

Referring to FIGS. 8A and 8B, the method includes forming a plurality of trenches 13 in a first etching process of the type explained with reference to FIGS. 6A and 6B. FIG. 8A shows a vertical cross sectional view of the semiconductor body 10 and the etch mask 20 and FIG. 8B shows a horizontal cross sectional view of the semiconductor body 10 after this etching process. The method further includes a second etching process of the type explained with reference to FIGS. 6C and 6D. FIG. 8C shows a vertical cross sectional view of the semiconductor body 10 and the etch mask 20 and FIG. 8D shows a horizontal cross sectional view of the semiconductor body 10 after the second etching process. In this second etching process more than one cavity is formed. Just for the purpose of illustration, the arrangement shown in FIGS. 8C and 8D includes two cavities. In the method explained with reference to FIGS. 6A-6D, after the first etching process that forms the plurality of trenches 13 mesa regions of the semiconductor body 10 remain below the bridges 22 of the etch mask 20 and between the trenches. These mesa regions have essentially the same width and are removed in the second etching process explained with reference to FIGS. 6C and 6D. The “width” of the individual mesa regions is the shortest distance between two neighbouring trenches 13. In the example shown in FIGS. 8A-8F, the etch mask 20 includes at least one bridge 22′ that is wider than the other bridges 22, so that a mesa region remaining below this bridge 22′ after the first etching process is wider than the other mesa regions. A duration of the second etching process is such that the mesa regions below the bridges 22 are removed but that a section of the mesa region below the wider bridge 22′ remains. This is illustrated in FIGS. 8C and 8D.

Referring to FIGS. 8E and 8F, the method further includes an oxidation process of the type explained with reference to FIGS. 7B and 7C. FIG. 8A shows a vertical cross sectional view of the semiconductor body 10 and the etch mask 20 and FIG. 8F shows a horizontal cross sectional view of the semiconductor body 10 after this oxidation process. In this oxidation process, an oxide region 14 is formed along bottoms and sidewalls of the cavities 12₁, 12₂. According to one example, a temperature and a duration of this oxidation process is such that the mesa region remaining between the cavities 12₁ and 12₂ after the second etching process is completely oxidized. The cavities 12₁, 12₂ may be closed by closing the openings 21 in the same way as explained with reference to FIGS. 1E an 7D herein before.

In the examples explained before, the first etching process may include a dry etching process, which is an etching process that uses a gaseous etchant, or a wet etching process, and the second etching process may include a dry etching process or a wet etching process. A dry etching process, however, is usually more expensive than a wet etching process. In a dry etching process usually only one wafer can be processed in a process chamber at the same time, while a wet etching process usually is a batch process in which a plurality of wafers can be processed at the same time.

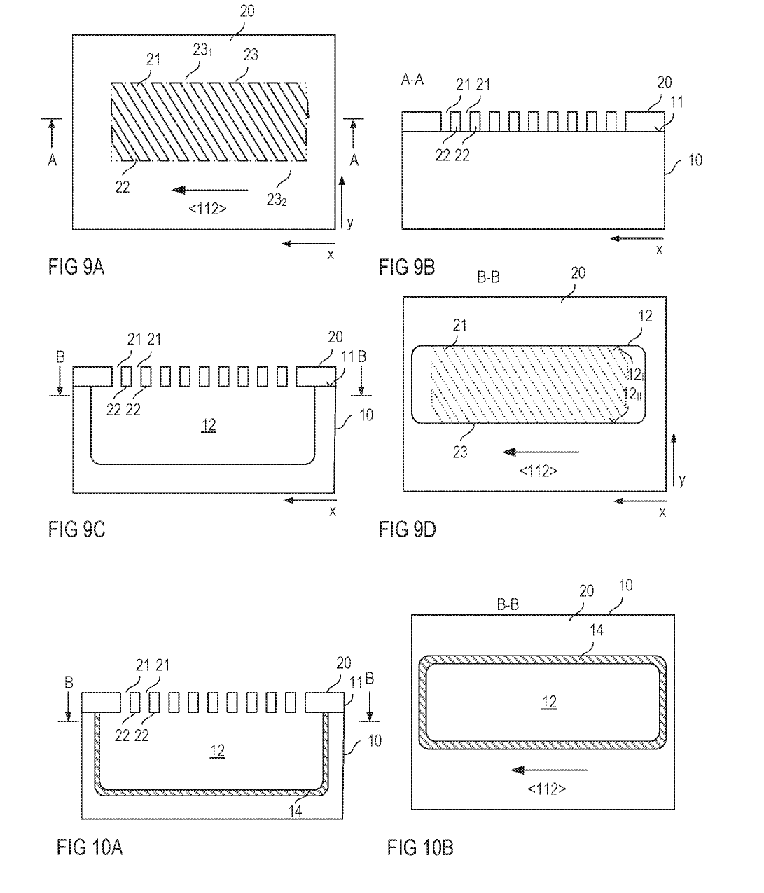

FIGS. 9A-9D illustrate one example of a method that may use a wet etching process for forming the cavity 12. This method makes use of the fact that certain wet etchants have an etch rate in certain types of semiconductor materials that is strongly dependent on an orientation of a crystal lattice in the semiconductor body. An alkaline etchant, for example, in a monocrystalline silicon semiconductor body, for example, etches surfaces lying in a {111} plane of the crystal lattice much slower than surfaces in other crystal planes of the crystal lattice. An alkaline etchant includes, for example, TMAH (tetramethylammoniumhydroxide), KOH (potassium hydroxide), CaOH (calcium hydroxide), or NH₄OH (ammonium hydroxide solution). KOH, for example, etches planes other than (111) planes, such as (100) planes, {110} planes, {210) planes, etc., in silicon at least 60 times faster than {111} planes (see, for example, Mitsuhiro Shikida, et al.: “Comparison of Anisotropic Etching Properties between KOH and TMAH Solutions”, Technical Digest. IEEE International MEMS 99 Conference. Twelfth IEEE Intemational Conference on Micro Electro Mechanical Systems (Cat. No. 99CH36291), Orlando, Fla., USA, 1999, pp. 315-320.)

FIGS. 9A and 9B show a top view (FIG. 9A) and a vertical cross sectional view (FIG. 9B) of the semiconductor body 10 and the etch mask 20 before the wet etching process. According to one example, the semiconductor body 10 is a monocrystalline silicon semiconductor body with the first surface 11 being in {110} plane of the crystal lattice of the semiconductor body 10, the patterned section 23 (which is illustrated in dotted line in FIG. 9A) has the form of a parallelogram and is oriented such that two opposite sides of the parallelogram run parallel to <112> directions of the crystal lattice of the semiconductor body 10 below the etch mask 20. The parallelogram formed by the shape of the patterned section 23 is a rectangle in the example shown in FIG. 9A. This, however, is only an example. Any other type of parallelogram may be used as well. The openings 21 are elongated openings and extend between those two opposing sides of the parallelogram that extend in the <112> direction. These openings 21 are inclined relative to <112> direction, so that these elongated openings 21 are not parallel to the <112> direction. According to one example angles between the elongated openings 21 and the <112> direction are between 20° and 70°, in particular between 30° and 60°.

A silicon semiconductor body in which the first surface lies in a {110} crystal plane is referred to as {110} semiconductor body in the following. In a {110} semiconductor body. {111} planes are perpendicular to the {110} planes in <112> directions (see, for example, P. Pal and S. Singh, “A New Model for the Etching Characteristics of Corners Formed by Si{111} Planes on Si{110} Wafer Surface.” Engineering, Vol. 5 No. 11A, 2013, pp. 1-8. doi: 10.4236/eng.2013.511A001.) Thus, in the semiconductor body 10 shown in FIG. 9A, {111} planes are perpendicular to the first surface 11 along the opposite sides of the parallelogram.

FIG. 9C shows a vertical cross sectional view of the semiconductor body 10 and the etch mask 20 and FIG. 9D shows a horizontal cross sectional view of the semiconductor body 10 in a horizontal section plane B-B after a wet etching process using an alkaline etchant. In FIG. 9D, reference characters 12_{I} and 12_{II} denote sidewalls of the cavity 12 formed in the wet etching process. The position of these sidewalls is mainly defined by those sides of the parallelogram of the patterned section 23 that extend in the <112> direction. These sidewalls 12₁, 12₂ lie in {111} planes of the crystal lattice. This is explained below.

In the etching process, the cavity 12 is formed below the patterned section 23 of the etch mask 20 as follows: In the beginning of the etching process, the etchant gets in touch with the semiconductor body 10 in those regions uncovered by the openings 21 so that trenches that are substantially aligned with the openings 21 are etched. These trenches extend from one {111} plane in the crystal lattice of the semiconductor body 10 to another {111} plane in the crystal lattice, which is by virtue of the fact, that the first surface 11 is in the {110} plane and that the sides of the parallelogram formed by the patterned section 23 between which the openings 21 extend run in <112> directions of the crystal lattice. When trenches have been etched into the semiconductor body 10 below the openings 21 the etchant does essentially not etch {111} planes, that is, essentially not in directions perpendicular to the <112> direction. By this, semiconductor material below the bridges 22 is removed and the cavity 12, in the <112> direction also extends below the etch mask 20. In directions perpendicular to the <112> direction, however, the dimension of the cavity 12 is mainly defined by the dimension of the patterned section 23 of the etch mask. This is illustrated in FIG. 9D, in which a position of the openings 21 of the etch mask above the cavity 12 is illustrated in dotted lines.

According to one example, an insulation layer, such as an oxide layer is formed on a bottom and sidewalls of the cavity 12, if such insulation layer has not yet been formed in the process of forming the at least one cavity 12. The methods explained with reference to FIGS. 7A-7D and 8A-8F include forming an oxidation layer 14 on sidewalls and a bottom of each cavity so that there is no need to additionally form such insulation layer. In the examples explained with reference to FIGS. 6A-6D and 9A-9D an insulation layer may be formed on sidewalls and a bottom of the cavity 12 after forming the cavity 12 and before forming the sealing layer 13. Forming such insulation layer may include a thermal oxidation process. FIG. 10A shows a vertical cross sectional view of the semiconductor body 10 and the etch mask 20 and FIG. 10B shows a horizontal cross sectional view of the semiconductor body 10 after such thermal oxidation process that forms an oxidation layer 14 along sidewalls and a bottom of the cavity 12.

A trench insulation structure formed in accordance with any of the methods explained before may be used in various types of semiconductor devices and in various ways. This is explained in the following with reference to examples.

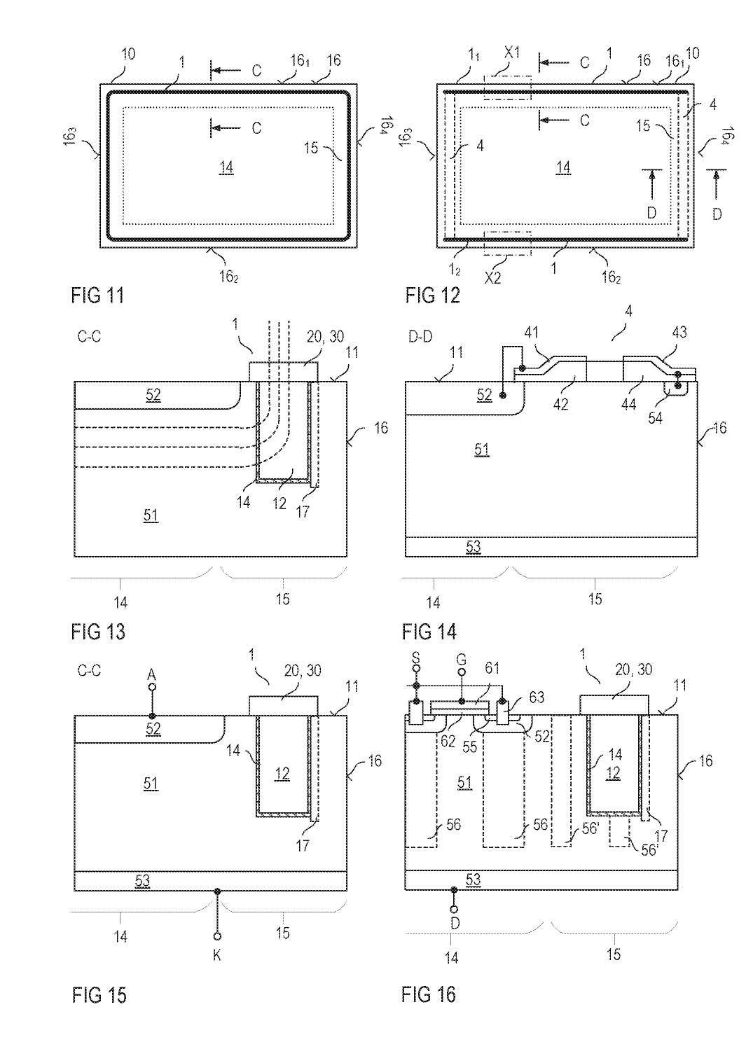

FIG. 11 shows a top view of a semiconductor body 10. This semiconductor body 10 includes an inner region 14 and an edge region 15. The edge region 15 surrounds the inner region 14 and is arranged between the inner region 14 and an edge surface 16 of the semiconductor body 10. The edge surface 16 terminates the semiconductor body 10 in lateral directions. Just for the purpose of illustration the semiconductor body 10 is of rectangular form in the example shown in FIG. 11, so that the edge surface 16 has four surface section 16₁, 16₂, 16₃, 16₄. The trench insulation structure 1, which is drawn as a bold line in FIG. 11, is part of an edge termination structure in the example shown in FIG. 11, is arranged in the edge region 15, and completely surrounds the inner region 14. That is, the trench insulation structure 1 has four section in this example, wherein these sections form a closed loop around the inner region and wherein each of these section is essentially parallel to a corresponding one of the edge surface section 16₁-16₄. The inner region 14 of the semiconductor body 10 may include active device regions of a semiconductor device. Examples of semiconductor devices are explained with reference to FIGS. 15 and 16 below.

FIG. 12 shows a modification of the arrangement shown in FIG. 11. In this example the trench insulation structure includes two separate sections, a first section 1₁ that essentially runs parallel to edge surface section 16₁ in the edge region 15; and a second section 1₂ that essentially runs parallel to edge surface section 16₂ in the edge region 15 whereas edge surface section 16₂ is opposite edge surface section 16₁. Optionally, the semiconductor device includes planar edge termination structures 4 in those sections of the edge region 15 that do not include the trench insulation structure 1.

The function of the trench insulation structure 1 in an edge termination structure of a semiconductor device is explained with reference to FIG. 13, which shows a vertical cross sectional view of one of the semiconductor bodies shown in FIGS. 11 and 12 in a section plane C-C that cuts through the edge region 15 in a section where the trench insulation structure 1 is located and through a section of the inner region 14. In FIG. 13, only those regions of a semiconductor device necessary to understand the function of the trench insulation structure 1 are shown. Examples of specific semiconductor devices that include a structure of the type shown in FIG. 13 are explained with reference to FIGS. 15 and 16 further below. FIG. 13 shows the trench insulation structure 1 with the cavity 12 covered by the cover 20, 30 (which is only schematically illustrated in FIG. 13) and with the insulation layer 14 along sidewalls and bottom of the cavity 12.

The trench insulation structure 1 is part of an edge termination structure that serves to control an electric field in the edge region of the semiconductor device 15. In the inner region, the semiconductor device includes a pn-junction between a first semiconductor region 51 of a first doping type (conductivity type) and a second semiconductor region 52 of a second doping type (conductivity type) complementary to the first doping type. The edge termination structure may further include a field-stop region 17 between the trench insulation structure 1 and the edge surface 16. The field-stop region 17 may adjoin the trench insulation structure 1 on a side that faces the edge surface 16. According to one example, the field-stop region 17 has the same doping type as the first semiconductor region 51, but is more highly doped. According to one example, a dopant dose in the field stop region 17 (in a direction perpendicular to the trench sidewall) is higher than 2E12 cm⁻², such as about 1E13 cm⁻².

If the pn-junction between the first semiconductor region 51 and the second semiconductor region 52 is reversed biased by applying a voltage between the first semiconductor region 51 and the second semiconductor region 52 a depletion region (space charge region) expands in the first semiconductor region 51 and the semiconductor region 52. For the purpose of illustration it is assumed that the first semiconductor region 51 has a significantly lower doping concentration than the second semiconductor region 52, so that the depletion region mainly expands in the first semiconductor region 51. This depletion region is associated with an electric field, wherein equipotential lines of this electric field are illustrated in dashed lines in FIG. 13. These equipotential are essentially parallel to the first surface 11 in the inner region and enter the trench insulation structure 1 in the edge region 15. In the trench insulation structure 1 the equipotential lines are “bent” upwards, so that the equipotential lines leave the arrangement through the trench insulation structure 1. In those regions, where the equipotential lines are curved a higher field strength may occur than in those regions where the equipotential lines are essentially parallel. These curved sections, however, are inside the trench insulation structure 1 so that peaks of the electric field in the semiconductor body 10 are avoided. The equipotential lines are bent upwards in the trench insulation structure 1 by virtue of the field stop region 17, wherein this upward bending is supported by the fact that a (relative) dielectric number of the materials of the trench insulation structure 1 is lower than the dielectric number of the semiconductor material. In silicon, for example, the relative dielectric number is 11.7, whereas the relative dielectric number of silicon oxide, which may be used as the insulation layer 14, is 3.7. The cavity 12 is filled with a gas, which may be air or any other gas entering the cavity 12 before closing the openings 21 or diffusing from the semiconductor body 10 into the cavity 12 after closing the openings 21. The dielectric number of those gases is about 1.

In particular, the trench insulation structure 1 ensures that a semiconductor mesa region between the field stop region 17 and the edge surface 16 is free of an electric field during operation of the semiconductor device, while a (relatively low) field may occur in the field stop region 17. According to one example, the first semiconductor region 51 is included in the inner region 14 and the edge region 15.

FIG. 14 shows one example of a planar edge termination structure 4. The edge termination structure 4 according to this example includes two field rings 41, 43 on top of the first surface 11 of the semiconductor body 100. According to one example, a first field ring 41 is electrically connected to the second semiconductor region 52, and a second field ring 43 is electrically connected to the first semiconductor region 51 in the edge region 15. For this, the second field ring may be connected to a region of the same doping type as the first semiconductor region 51, but more highly doped than the first semiconductor region 51. The field rings 41, 43 include an electrically conducting material such as, for example, polysilicon. Those field rings 41, 43 may be separated from the first surface 11 by insulation layers 42, 44.

FIG. 15 shows a vertical cross-sectional view of the edge region 15 and one section of the inner region 14 of a vertical bipolar diode that is based on the structure shown in FIG. 13. In this diode, the first semiconductor region 51 forms a base region and the second semiconductor region 52 forms a first emitter region. A third semiconductor region 53 adjoins the first region 51 and is spaced apart from the second semiconductor region 52 in the vertical direction of the semiconductor body 10. The third region 53 has the same doping type as the first region 51 but a higher doping concentration and forms a second emitter region of the diode. According to one example, the first emitter region 52 is p-doped and connected to an anode node A and the second emitter 53 is n-doped and connected to a cathode node C. In this diode, a depletion region expands in the drift region 51 if a voltage is applied between the anode node A and the cathode node C that reverse biases the pn-junction between the first emitter region 52 and the drift region 51. Doping concentrations of the emitter regions 52, 53, for example, are selected from between 1E17 cm⁻³ and 1E21 cm⁻³, and a doping concentration of the drift region, for example, is selected from between 1E13 cm⁻³ and 1E16 cm⁻³.

FIG. 16 shows a vertical cross-sectional view of the edge region 15 and one section of the inner region 14 of a vertical transistor device that is based on the structure shown in FIG. 13. In this transistor device, the first semiconductor region 51 forms a drift region and the second semiconductor region 52 forms a body region. A third semiconductor region 53, which is spaced apart from the body region 52 in the vertical direction of the semiconductor body 10 forms a drain region. Further, the transistor device includes a source region 55 separated from the drift region 51 by the body region 52, and a gate electrode 61 adjacent the body region 52 and dielectrically insulated from the body region 52 by a gate dielectric 62. Just for the purpose of illustration, in the example shown in FIG. 16, the gate electrode 61 is drawn as a planar gate electrode arranged above the first surface 11 of the semiconductor body 10. This, however, is only an example. According to another example (not shown) the gate electrode 61 and the gate dielectric 62 are arranged in trenches that, from the first surface 11, extend into the semiconductor body 10.

The transistor device may include a plurality of transistor cells, with each transistor cell including a source region 55, a body region 52, and a gate electrode 61. Some of those transistor cells are shown in FIG. 16. The individual transistor cells may share the drift region 51 and the drain region 53 and are connected in parallel by having their source and body regions 55, 52 electrically connected to a common source node S and by having their gate electrodes 61 electrically connected to a common gate node G. Source electrodes 63 that electrically connect the source and body regions 55, 52 of the individual transistor cells to the source node S are schematically illustrated in FIG. 16.

The transistor device can be implemented as an n-type transistor device or as a p-type transistor device. The type of the transistor device is defined by the doping type of the source region 55. In an n-type transistor device, the source region 55 and the drift region 51 are n-doped, while the body region 52 is p-doped. In a p-type transistor device, the doping types of the source region 55, the body region 52 and the drift region 51 are complementary to the doping types in an n-typed transistor device. Further, the transistor device can be implemented as a MOSFET or an IGBT. In a MOSFET, the drain region 53 has the same doping type as the source region 55, while in an IGBT the drain region (which is also referred to as collector region in an IGBT) has a doping type complementary to the doping type of the source region 55. Doping concentrations of the individual device regions are, for example, selected from the following ranges: source region 55: between 1E19 cm⁻³ and 1E21 cm⁻³; drain region 53: between 1E17 cm⁻³ and 1E21 cm⁻³: drift region 51: between 1E13 cm⁻³ and 1E16 cm⁻³; body region 52: between 1E17 cm⁻³ and 1E19 cm⁻³.

Optionally, the transistor device includes compensation regions 56 of a doping type complementary to the doping type in the drift region 51. These compensation regions, which are illustrated in dashed lines in FIG. 16, adjoin the body regions 52 and the drift region 51 and, according to one example, are spaced apart from the drain region 53. The transistor device may include compensation regions 56 not only in the inner region 14, but may also include compensation regions 56′ in the edge region 15. According to one example, the compensation regions 56′ in the edge region 15 are floating. That is, these compensation regions 56′ are neither dielectrically connected to the source node S, like the compensation regions 56 in the inner region 14, nor to the drain node D.

The transistor device can be operated in an on-state and an off-state. The transistor device is in the on-state when a voltage is applied between the gate node and the source node S such that the gate electrode 61, by field effect, generates a conducting channel in the body region 52 between the source region 55 and the drift region 61. In the off-state of the transistor device, this conducting channel is interrupted. A depletion region expands in the drift region 51 when the transistor device is in the off-state and when a voltage is applied between the drain node D and the source node S that reverse biases the pn-junction between the body regions 52 and the drift region 51.

Referring to FIGS. 13, 15 and 16, the edge termination structure may include a field-stop region 17 between the trench insulation structure 1 and the etch surface 16. As shown in the examples, the field-stop region 17 may adjoin the trench insulation structure 1 on a side that faces the etch surface 16. According to one example, the field-stop region 17 has the same doping type as the first semiconductor region 51, but is more highly doped. According to one example, a dopant dose in the field stop region 17 (in a direction perpendicular to the trench sidewall) is higher than 2E12 cm², such as about 1E13 cm².

The semiconductor body 10 may include a semiconductor substrate and at least one epitaxial layer grown on top of the substrate. In semiconductor devices of the type shown in FIGS. 15 and 16, the substrate may form the third semiconductor region 53 (the second emitter region in a diode or the drain region 53 in a transistor) while the other active device regions as well as the trench insulation structure 1 may be formed in the at least one epitaxial layer grown on top of the substrate. According to one example, in a transistor device of the type shown in FIG. 16, the drift region 51, the optional compensation regions 56, 56′ and the body regions 52 are formed when growing the at least one epitaxial layer on the substrate. The epitaxial process may include forming a plurality of epitaxial layers one above the other and implanting dopant atoms into the individual epitaxial layers to form the drift region 51, the optional compensation regions 56 and the body regions 52. According to one example (not shown), the field-stop region 17 is formed in this epitaxial process, whereas the cavity 12 of the trench insulation structure 1, which is formed after the epitaxial process has been completed, is aligned to the field-stop region 17 such that field-stop region 17 adjoins the cavity 12 and the optional insulation layer 14 of the trench insulation structure 1.

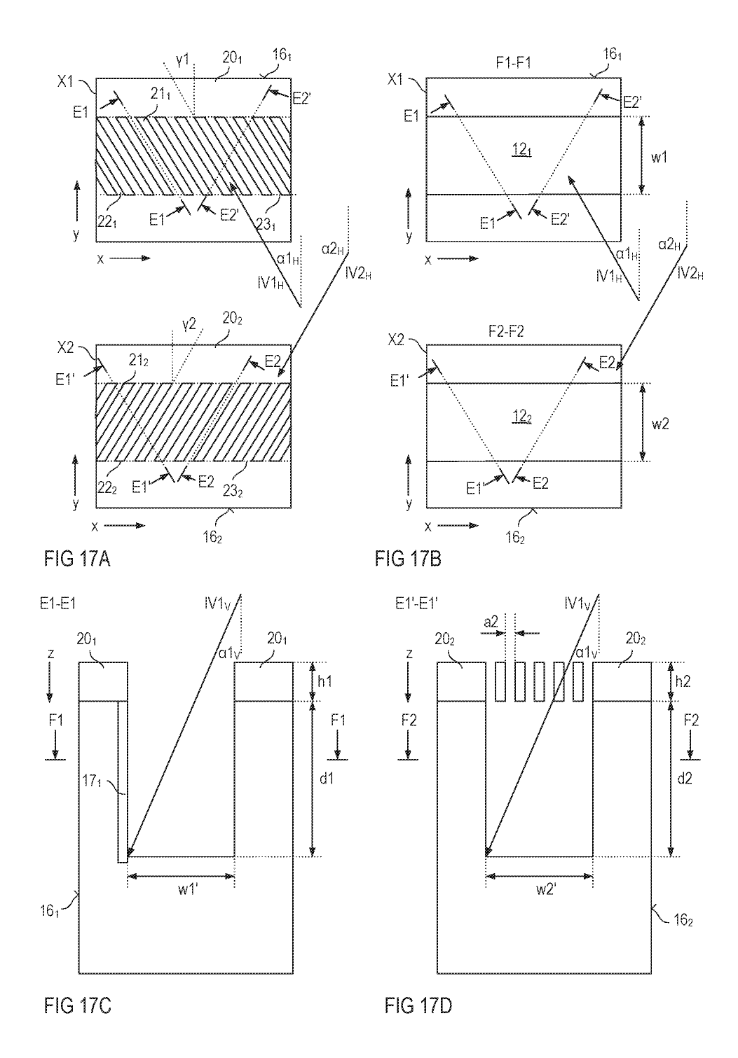

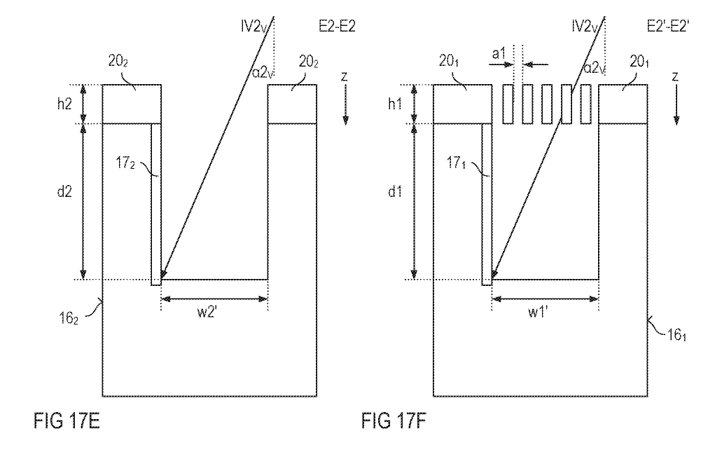

According to another example, the field-stop region 17 is formed by an implantation process after the cavity 12 has been formed but before the cavity 12 is sealed by the sealing layer 30. One example of a method that forms a field-stop region in a semiconductor device of the type shown in FIG. 12 is explained with reference to FIGS. 17A to 17F below. In this method, forming the field-stop region includes forming a first field-stop region section between the first section 1₁ of the trench insulation structure and the first edge surface section 16₁ and a second field-stop region section between the second section 1₂ of the trench insulation structure 1 and the second edge surface section 16₂. In FIG. 12, X1 and X2 denote two different sections of the transistor device, a first section X1 includes a section of the edge region 15 in an area where the first insulation structure section 1₁ and the first edge surface section 16₁ are located, and a second section X2 includes a section of the edge region 15, where the second trench insulation structure section 1₂ and the second edge surface section 16₂ are located. FIGS. 17A to 17F show top views, horizontal cross-sectional views and vertical cross-sectional views, respectively, of these sections X1, X2 during different process steps.

FIG. 17A shows top views of sections X1, X2 and FIG. 17B shows horizontal cross-sectional views of sections X1, X2 after the etch mask has been formed on the semiconductor body 10 and a cavity has been formed below each patterned section of the etch mask. In FIG. 17A, reference character 20₁ denotes the etch mask in the first section X1, reference characters 21₁, 22₁ denote openings and bridges of the etch mask 20₁ in this first section X1, and reference character 23₁ denotes the patterned section of the etch mask 20₁. This patterned section 23₁ is referred to as first patterned section in the following. Equivalently, reference character 20₂ denotes the etch mask in the second section X2, reference characters 21₂, 22₂ denote openings and bridges of the etch mask 20₂ in this second section X2, and reference character 23₂ denotes the patterned section of the etch mask 20₂. This patterned section 23₂ is referred to as second patterned section in the following. Further, the etch mask 20₁ in the first section X1 is referred to as first etch mask, the etch mask 20₂ in the second section X2 is referred to as second etch mask, the trench 12₁ in the first section X1 is referred to as first trench, and the trench 12₂ in the second section X2 is referred to as second trench. Those sidewalls of the first and second trench 12₁, 12₂ that face the edge surface 16 are referred to as first sidewalls and the opposite sidewalls are referred to as second sidewalls.

In FIG. 17B, reference character 12₁ denotes one cavity formed below the openings and the bridges 21₁, 22₁ of the etch mask 20₁ in the first section X1, and reference character 12₂ denotes one cavity formed below the openings 21₂ and bridges 22₂ below the etch mask 20₂ in the second section X2. Each of the patterned sections 23₁, 23₂ may be elongated in a first lateral direction x of the semiconductor body 10 to form elongated cavities and, therefore, elongated trench insulation structures 1₁, 1₂ of the type shown in FIG. 12. In the example shown in FIG. 17A, each of the patterned sections 23₁, 23₂ includes a plurality of elongated and essentially parallel openings 21₁, 21₂. The elongated openings 21₁ of the first patterned section 23₁, in horizontal plane parallel to the first surface 11 of the semiconductor body 10, have an orientation that is different from an orientation of the elongated openings 21₂ of the second patterned section 23₂ such that an angle γ₁ between the elongated openings 21₁ in the first patterned section 23₁ and a second lateral direction y is different from an angle γ2 between the elongated openings 21₂ in the second patterned section 23₂ and the second lateral direction y. According to one example, the second lateral direction y is perpendicular to the first lateral direction x. Each of the angles γ1, γ2 is different from zero, so that none of the openings 21₁, 21₂ is parallel to the second lateral direction y. Furthermore, the first and second angle α1, α2 have different signs. According to one example, the angles γ1 and γ2 have the same absolute value but different signs, so that γ1=−γ2. According to another example, the absolute value of each of these angles γ1, γ2 is selected from a range of between 20° and 70°, in particular between 30° and 60°, so that, for example, γ1 is between 20° and 70° and γ2 is between −20° and −70°.

Forming the field-stop region 17 includes two implantation processes using different implantation angles, a first implantation angle α1 in a first implantation process and a second implantation α2 in a second implantation process. Each of these implantation angles is a solid angle with a first component α1_{H}, α2_{H} in a horizontal plane of the semiconductor body 10 and a second component α1_{V}, α2_{V} in a vertical plane of the semiconductor body 10. The horizontal plane is a plane parallel to the first surface 11 and the vertical plane is a plane perpendicular to the first surface 11. The first components α1_{H}, α2_{H} are also referred to as horizontal components and the second components are also referred to as vertical components in the following.

In FIGS. 17A-17F, the two implantation processes are represented by implantation vectors IV1, IV2; a first implantation vector IV1 represents a first direction in which the etch mask 20 is irradiated with dopant atoms in the first implantation process and a second implantation vector IV2 represents a second direction in which the etch mask 20 is irradiated with dopant atoms in the second implantation process. The etch mask 20 acts as an implantation mask in these implantation processes. A spatial orientation of the first implantation vector IV1 is given by the first implantation angle α1 and a spatial orientation of the second implantation vector is given by the second implantation angle α2.

FIGS. 17A and 17B, which show a top view of the etch mask 20₁, 20₂ and a horizontal cross sectional view of the semiconductor body, respectively, schematically illustrate horizontal components IV1_{H}, IV2_{H} of the first and second implantation vectors IV, IV2. The orientation of these horizontal components IV1_{H}, IV2_{H} in the horizontal plane is given by the horizontal components α1_{H}, α2_{H} of the first and second implantation vectors. As explained below, the first implantation process implants dopant atoms into the first sidewall of the first cavity 12₁ and the second implantation process implants dopant atoms into the first sidewall of the second cavity 12₂. The first implantation process is explained with reference to FIGS. 17A-17B and 17C-17D and the second implantation process is explained with reference to FIGS. 17A-17B and 17E-17F below.

Basically, in the first implantation process, the first implantation vector IV1 is orientated such that the dopant atoms are implanted through the openings 21₁ of the first etch mask 20₁ into the first sidewall of the first trench 12₁ and that the second etch mask 20₂ prevents dopant atoms from entering the second trench 12₂. According to one example, implanting dopant atoms through the openings 21₁ of the first etch mask 20₁ into the first sidewall of the first trench 12₁ is obtained by the horizontal component IV1_{H} of the first implantation vector IV1 being essentially parallel to the openings 21₁ in the first etch mask. According to one example, this is obtained by the horizontal component α1_{H} of the first implantation vector IV being essentially equal the angle γ1 between the first openings 21₁ and the second horizontal direction γ, α1_{H}=γ1. In the following, the horizontal component α1_{H} of the first implantation vector is also first rotation angle as it defines a rotation of the semiconductor body 10 relative to an implantation source (which is not shown in the drawings).

FIG. 17C shows the vertical component IV1_{V} of the first implantation vector IV1 in the first implantation process in a vertical plane E1-E1. This plane E1-E1 is perpendicular to the first surface 11 of the semiconductor body 10 and has an orientation that is defined by the horizontal component IV1_{H} of the first implantation vector IV1. An orientation of the vertical component IV1_{V} in this vertical plane E1-E1 is defined by the second component α1_{V} of the first implantation angle α1, that is, an inclination of the vertical implantation vector component IV1_{V} relative to the vertical direction z of the semiconductor body 10 is given by α1_{V}, which is also referred to as first tilt angle in the following. According to one example, the first tilt angle α1_{V} is selected such that dopant atoms are implanted into the first sidewall of the first cavity 12₁ along a complete length d1 of the first sidewall in the vertical direction z. The length of the first sidewall equals a depth of the first cavity 12₁. If, for example, the length/depth is d1, h1 is a thickness of the first etch mask 20₁ and w1′ is a distance between the sidewalls of the first cavity 12₁ in the longitudinal direction of the openings 21₁, the first tilt angle α1_{V} can be obtained as:

$${α1}_{V} < arctan ( \frac{w {1}^{′}}{d 1 + h 1} ) . \qquad ( 1 a )$$

However, forming the field-stop region 17 such that it extends along the complete length d1 of the first sidewall in the vertical direction z is only one example. According to another example, the field stop region 17 is formed only in a upper sidewall section of the first sidewall. In this case, the first tilt angle α1_{V} can be greater than arctan

$$( \frac{w {1}^{′}}{d 1 + h 1} ) .$$

The distance between the sidewalls of the first cavity 12₁ in the longitudinal direction of the openings 21₁ is given by

$$w {1}^{′} = \frac{w 1}{cos ( {α1}_{H} )} , \qquad ( 2 a )$$

where w1, referring to FIG. 17A, is the width of the first cavity 12₁, which is the shortest distance between the sidewalls of the first cavity 12₁ (that is, the distance in a direction perpendicular to the sidewalls).

In the first implantation process, the second etch mask 20₂, more particularly, the bridges 22₂ of the second etch mask 20₂ prevent dopant atoms from being implanted into the second cavity 12₂, so that dopant atoms are not implanted into a sidewall of the second cavity 12₂ that faces away from the second edge surface section 16₂. For this, the horizontal component IV1_{H} of the first implantation vector IV1 is not parallel with the elongated openings 21₂ in the first etch mask 20₂. Further, a height h2 of the etch mask 20₂ and a distance a2 of neighboring bridges 22₂ in the horizontal direction of the first implantation vector IV1 are chosen such that dopant atoms cannot pass the second etch mask 20₂. According to one example, an angle between the horizontal component IV1_{H} of the first implantation vector IV1 and longitudinal directions of the openings 21₁ in the first etch mask 20₁ is greater than 20°, in particular greater than 45°.

FIG. 17D illustrates a vertical cross-sectional view of the second section X2 in a section plane E1′-E1′ that is parallel to the section plane E1-E1 shown in FIG. 17C. In FIG. 17D, a2 denotes a distance between two adjacent bridges 22₂ in the section plane E1′-E1′, which represents a direction of the horizontal component IV1_{H} of the first implantation vector IV1. This distance α1 is adapted to a thickness h2 of the first etch mask 20₂ such that, given the vertical component of the first implantation vector IV1_{V}, dopant atoms are not implanted into the second cavity 12₂. In particular, an aspect ratio h2/a2 of the openings is adapted to the vertical component of the first implantation vector IV1_{V} such that dopant atoms are not implanted into the second cavity 12₂. According to one example, this is obtained by selecting the distance a2 and the thickness h2 of the second etch mask 20₂ dependent on the first tilt angle α1_{V} such that

$$\frac{a 2}{h 2} < tan ( {α1}_{V} ) \qquad ( 3 a )$$

and selecting an implantation energy such that particles are not implanted through the mask 20₂. In the second implantation process, the second implantation vector IV2 is orientated such that the dopant atoms are implanted through the openings 21₂ of the second etch mask 20₂ into the first sidewall of the second trench 12₂ and that the first etch mask 20₁ prevents dopant atoms from entering the first trench 12₁. According to one example, implanting dopant atoms through the openings 21₂ of the second etch mask 20₂ into the first sidewall of the second trench 12₂ is obtained by the horizontal component IV2_{H} of the second implantation vector IV2 being essentially parallel to the openings 21₂ in the second etch mask. According to one example, this is obtained by the absolute value |α2_{H}| of the rotation angle being equal to the absolute value |γ2| of the angle γ2 between the longitudinal direction of the openings 21₂ and the second horizontal direction y. More specifically, according to one example, the second rotation angle is given by

α2_{H}=180°+γ2 (4).

FIG. 17E shows the vertical component IV2_{V} of the second implantation vector IV2 in the second implantation process in a vertical plane E2-E2 that is perpendicular to the first surface 11 of the semiconductor body 10 and has an orientation that is defined by the horizontal component IV2_{H} of the second implantation vector IV2. An orientation of the vertical component IV2_{V} in this vertical plane E2-E2 is defined by the second component α2_{V} of the second implantation angle α2, whereas this second component α2_{V} is also referred to as second tilt angle in the following. According to one example, the second tilt angle α2_{V} is selected such that dopant atoms are implanted into the first sidewall of the second cavity 12₁ along a complete length d1 of the first sidewall in the vertical direction z. The length of the first sidewall equals a depth of the second cavity 12₂. If, for example, the length/depth is d2, h2 is a thickness of the second etch mask 20₂ and w2′ is a distance between the sidewalls of the second cavity 12₂ in the longitudinal direction of the openings 21₂, the second tilt angle α2_{V} can be obtained as:

$${α2}_{V} < arctan ( \frac{w {2}^{′}}{d 2 + h 2} ) . \qquad ( 1 b )$$

However, forming the field-stop region 17 such that it extends along the complete length d1 of the first sidewall in the vertical direction z is only one example. According to another example, the field stop region 17 is formed only in a upper sidewall section of the first sidewall. In this case, the first tilt angle α2_{V} can be greater than arctan

$$( \frac{w {2}^{′}}{d 2 + h 2} ) .$$

The distance between the sidewalls of the second cavity 12₂ in the longitudinal direction of the openings 21₂ is given by

$$w {2}^{′} = \frac{w 2}{cos ( {α2}_{H} )} , \qquad ( 2 b )$$

where w2, referring to FIG. 17A, is the width of the second cavity 12₂, which is the shortest distance between the sidewalls of the second cavity 12₂.

Referring to FIG. 17F, in the second implantation process, the first etch mask 20₁, more particularly, the bridges 22₁ of the first etch mask 20₁ prevent dopant atoms from being implanted into the first cavity 12₁, so that dopant atoms are not implanted into a sidewall of the first cavity 12₁ that faces away from the first edge surface section 16₁. FIG. 17F illustrates a vertical cross-sectional view of the first section X1 in a section plane E2′-E2′ that is parallel to the section plane E2-E2 shown in FIG. 17E. In FIG. 17F, α1 denotes a distance between two adjacent bridges 22₁ in the section plane E2′-E2′, which represents a direction of the horizontal component IV2_{H} of the second implantation vector IV2. This distance a2 is adapted to a thickness h1 of the first etch mask 20₁ such that, given the vertical component of the second implantation vector IV2_{V}, dopant atoms are not implanted into the first cavity 12₁. According to one example, this is obtained by selecting the distance a1 and the thickness h1 of the first etch mask 20₁ dependent on the second tilt angle α2_{V} such that

$$\frac{a 1}{d 2} < tan ( {α2}_{V} ) . \qquad ( 3 b )$$

According to one example, the depths d1, d2 of the first and second cavity 12₁, 12₂ are equal, so that d1=d2=d and the thickness of the etch mask is the same in the first and second sections X1, X2, so that h1=h2=h.

According to one example, in both implantation processes dopant atoms of the same doping type (n-type or p-type) are implanted. Examples of n-type dopants include phosphorous ions arsenic ions, and antimony ions. Examples of p-type dopants include aluminum ions and boron ions. According to one example, an implantation dose is selected from between 5E12 cm⁻² and 1E14 cm⁻². An implantation energy is dependent on the type of dopant. The implantation energy of phosphorous (P) is, for example, selected from a range of between 20 keV and 500 keV, in particular, between 50 keV and 100 keV. The implantation energy of boron (B) may be higher than that of P and, for example, is selected from a range of between 50 keV and 700 keV.

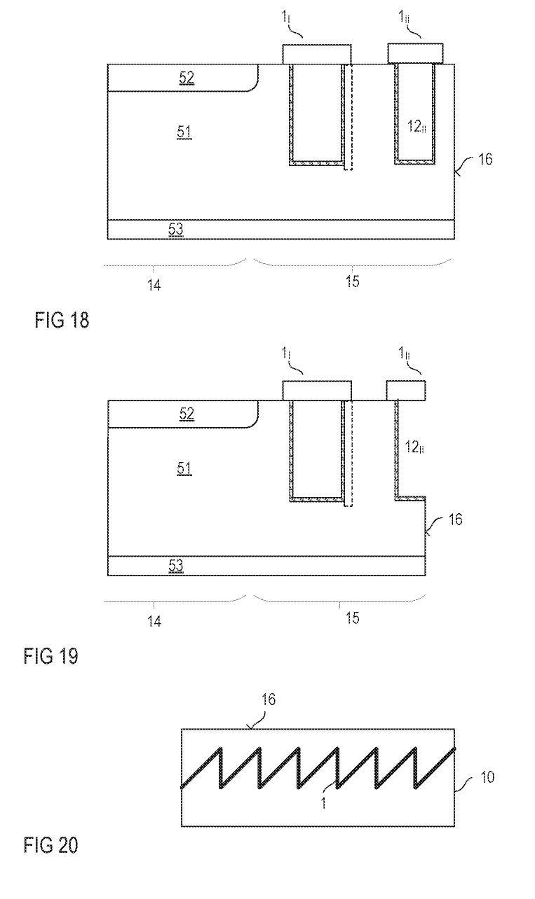

FIG. 18 shows a vertical cross-sectional view of an edge region 15 of a semiconductor device according to another example. In this example, the semiconductor device includes two trench insulation structures 1_{I}, 1_{II}. A first trench insulation structure 1₁ acts as an edge termination structure in this semiconductor device, and a second trench insulation structure 1_{II}, which is located between the first insulation structure 1_{I} and the etch surface 16 acts as a chipping stopper. This chipping stopper prevents cracks from expanding in the semiconductor body 10. Those cracks may result from cutting the semiconductor body 10 from a wafer with a plurality of semiconductor bodies, In this context it should be noted that the process sequences explained hereinbefore may be applied to a wafer that includes a plurality of semiconductor bodies so that a plurality of semiconductor bodies are processed at the same time. After the manufacturing process, the wafer can be cut so as to obtain a plurality of single semiconductor bodies. FIGS. 11 to 16 and 18 show the semiconductor body 10 after it has been separated from the wafer.

According to another example, cutting the semiconductor wafer to separate the individual semiconductor bodies includes cutting through the trench insulation structure 1_{II} acting as a chipping stopper. A result of this is shown in FIG. 19, which shows a vertical cross-sectional view of an edge region 15 of a semiconductor body that has been cut from a wafer in this way. In this example, a cavity 12_{II} of the second trench insulation structure 1_{II} is open towards the etch surface 16.

In the examples explained before, the trench insulation structure 1 includes two or more elongated sections, wherein each of these elongated sections is essentially parallel to one section of the edge surface 16. In the example shown in FIG. 11, for example, the trench insulation structure 1 includes four sections, with each of these sections being parallel to one section of the edge surface 16. In the example shown in FIG. 12 the trench insulation structure 1 includes two sections 1₁, 1₂, with each of these sections being parallel to one section 16₁, 16₂ of the edge surface 16. However, it is only one example for the trench insulation structure to include sections that are elongated and parallel to the edge surface 16.

FIG. 20 schematically illustrates a top view of one section of a semiconductor body 10 that includes a trench insulation structure according to another example. In this example, the trench insulation structure extends along a section of the edge surface, but is not parallel thereto. That is, a cavity of the trench insulation structure is not parallel to the edge surface. Instead, the trench insulation structure includes a plurality of adjoining sections arranged in a zig-zag-pattern.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method, comprising:
forming an etch mask on top of a surface of an edge region of a semiconductor body, the edge region surrounding an inner region of the semiconductor body, the etch mask comprising a plurality of openings and at least one bridge between the openings;
etching the semiconductor body at least in regions uncovered by the plurality of openings to form at least one cavity in the semiconductor body;
closing the plurality of openings such that the at least one cavity remains in the semiconductor body; and
forming active device regions of a semiconductor device in the inner region.

2. The method of claim 1, wherein etching the semiconductor body comprises etching the semiconductor body below the plurality of openings and below the at least one bridge such that at least one contiguous cavity is formed at least below several of the plurality of openings and below the at least one bridge between the several of the plurality of openings.

3. The method of claim 1, wherein etching the semiconductor body comprises etching the semiconductor body below the plurality of openings and below the at least one bridge such that one contiguous cavity is formed below the plurality of openings and the at least one bridge.

4. The method of claim 1, wherein etching the semiconductor body comprises etching the semiconductor body below the plurality of openings to form a plurality of cavities in the semiconductor body, and wherein the method further comprises oxidizing regions of the semiconductor body between the plurality of cavities.

5. The method of claim 4, wherein etching the semiconductor body comprises an anisotropic etching process.

6. The method of claim 1, wherein etching the semiconductor body comprises:
etching the semiconductor body below the plurality of openings in a first etching process to form a plurality of cavities in the semiconductor body; and
removing regions of the semiconductor body between the plurality of cavities in a second etching process.

7. The method of claim 1, wherein the surface lies in a (110) plane of a crystal lattice of the semiconductor body.

8. The method of claim 7, wherein etching the semiconductor body comprises a wet etching process using an alkaline etchant.

9. The method of claim 7, wherein the plurality of openings and the at least one bridge, in horizontal directions of the etch mask, define outer contours of a shape.

10. The method of claim 9, wherein the shape has a generally rectangular form.

11. The method of claim 9, wherein an orientation of the shape is such that two generally parallel sides extend in a <112> direction of the crystal lattice of the semiconductor body.

12. The method of claim 1, further comprising forming a doped region along a sidewall of the at least one cavity that faces away from the inner region.

13. The method of claim 12, wherein forming the doped region comprises a tilted implantation process using the etch mask as an implantation mask.

14. The method of claim 1, wherein the plurality of openings in the etch mask comprise a first plurality of openings on top of a first section of the edge region and a second plurality of openings on top of a second section of the edge region, and wherein the first region and the second region are spaced apart from each other such that the inner region is located between the first region and the second region.

15. The method of claim 1, wherein the plurality of openings in the etch mask comprise a first plurality of openings on top of a first section of the edge region and a third plurality of openings on top of a third section of the edge region, and wherein the first region and the third region are spaced apart from each other by a section of the edge region.

16. The method of claim 1, wherein the semiconductor body is part of a semiconductor wafer, and wherein after forming the at least one cavity in the semiconductor body, the method further comprises separating the semiconductor body by cutting the wafer.

17. The method of claim 16, wherein cutting the wafer comprises cutting the wafer distant to the at least one cavity.

18. The method of claim 16, wherein cutting the wafer comprises cutting the wafer through the at least one cavity.

19. The method of claim 1, wherein the etch mask comprises an insulating material, and wherein closing the plurality of openings comprises depositing an insulating material on the etch mask.

20. The method of claim 1, further comprising forming at least one transistor cell in the inner region of the semiconductor body.

21. A semiconductor device, comprising:
a semiconductor body with an inner region and an edge region;
active device regions in the inner region; and
a trench insulation structure arranged in the edge region, the trench insulation structure comprising:
at least one cavity filled with a gas in the semiconductor body; and
a cover on top of the cavity, the cover comprising a web having a plurality of openings and a material layer that at least one of fills and covers the plurality of openings.

22. The semiconductor device of claim 21, wherein the openings are elongated openings that are generally parallel to each other.

23. The semiconductor device of claim 21, wherein the cover comprises an oxide.

24. The semiconductor device of claim 21, wherein the gas comprises hydrogen gas.

25. The semiconductor device of claim 21, wherein the trench insulation structure surrounds the inner region.

26. The semiconductor device of claim 21, wherein the trench insulation structure comprises a first section and a second section, and wherein the first section and the second section are spaced apart from each other and arranged in edge region sections located on opposite sides of the inner region.

27. The semiconductor device of claim 21, wherein the semiconductor body comprises an edge surface, and wherein the semiconductor device further comprises a field-stop region between the cavity and the edge surface.

28. The semiconductor device of claim 21, wherein the semiconductor device is a vertical transistor device.

29. The semiconductor device of claim 21, wherein the semiconductor device is a vertical diode.

30. A method, comprising:
in a first irradiation process, irradiating with dopant particles a surface of a first implantation mask formed on an opening of a first cavity in a semiconductor body and a surface of a second implantation mask formed on an opening of a second cavity in the semiconductor body,
wherein the first irradiation process uses a first implantation vector,
wherein the first implantation mask comprises a plurality of openings oriented relative to the first implantation vector such that the dopant particles pass the first implantation mask and are implanted into a first sidewall of the first cavity,
wherein the second implantation mask comprises a plurality of openings separated by bridges, and
wherein the openings and bridges in the second implantation mask are oriented such that the dopant particles do not pass the second implantation mask.

31. The method of claim 30, wherein the plurality of openings in the first implantation mask are elongated and generally parallel, wherein the first implantation vector includes a horizontal component and a vertical component, and wherein the horizontal component is generally parallel with the plurality of elongated openings in the first implantation mask.

32. The method of claim 31, wherein the plurality of openings in the second implantation mask are elongated and generally parallel, wherein the horizontal component of the first implantation vector is not parallel with the plurality of elongated openings in the second implantation mask.

33. The method of claim 32, wherein an angle between the horizontal component of the first implantation vector and the elongated openings in the second implantation mask is greater than 20°.

34. The method of one of claim 30, further comprising:
irradiating the surface of the first implantation mask and the surface of the second implantation mask with dopant atoms in a second irradiation process using a second implantation vector,
wherein the plurality of openings in the second implantation mask are oriented relative to the second implantation angle such that the dopant atoms pass the second implantation mask and are implanted into a first sidewall of the second cavity,
wherein the first implantation mask comprises a plurality of bridges separating the plurality of openings, and
wherein the openings and bridges in the first implantation mask are oriented such that the dopant atoms do not pass the first implantation mask.
